(19) United States
(12) Patent Application Publication
(10) Pub. No.: US 2011/0278689 A1
(43) Pub. Date: Nov. 17, 2011

(54) SOLID-STATE IMAGING DEVICE AND MANUFACTURING METHOD THEREOF

(76) Inventor: Naoto NIISOE, Toyama (JP)

(21) Appl. No.: 13/069,125

(22) Filed: Mar. 22, 2011

(30) Foreign Application Priority Data
May 12, 2010 (JP) 2010-110465

(51) Int. Cl. H01L 27/146; H01L 31/18

(52) U.S. Cl. 257/432; 438/70; 257/E27.135; 257/E31.127

(57) ABSTRACT

A solid-state imaging device includes an n-type semiconductor substrate 203, a p-type well 204 provided in the substrate 203, photodiodes 201 arranged in a matrix above the substrate 203, and isolation regions 202 corresponding to the photodiodes 201. The isolation regions 202 each include a p-type first impurity diffusion layer 208. On a part of the p-type well 204 corresponding to the photodiode 201, an n-type first impurity diffusion layer 206 and a p-type impurity diffusion layer 207 that are to be formed as a light receiving part. Only immediately below the photodiode 201 corresponding to red pixels, an n-type second impurity diffusion layer 205 is provided. Immediately below the photodiode 201 corresponding to blue and green pixels, a p-type second impurity diffusion layer 209 is provided.

The disclosure of Japanese Patent Application No. 2010-110465 filed May 12, 2010 including specification, drawings and claims is incorporated herein by reference in its entirety.

### TECHNICAL FIELD

The present invention relates to a solid-state imaging device and a manufacturing method thereof, and particularly to a structure of an improved solid-state imaging device that can maintain preferable sensitivity characteristics while size of pixel part becomes reduced.

### BACKGROUND ART

Generally, a solid-state imaging device includes a pixel part composed of a plurality of pixels that are arranged in a matrix. Each pixel is composed of a light receiving part and a transfer part that are provided on a main surface of a semiconductor substrate. The light receiving part outputs an electrical signal in accordance with an incident light amount. The transfer part sequentially transfers accumulated electrical charges.

In recent years, with size reduction of solid-state imaging device (pixel part) and pixel density increase (also referred to simply as “size reduction of pixel part”), an area of a light receiving part has becomes reduced. This makes it difficult to secure sufficient sensitivity characteristics. Especially, red light has a long wavelength in terms of sensitivity characteristics. Accordingly, size reduction of the light receiving part caused by size reduction of pixel part cannot achieve sufficient sensitivity characteristics.

As an art for solving this problem, there has been proposed a method of obtaining a light receiving part by forming a plurality of impurity diffusion layers in a silicon substrate at a deep position from its surface. Photoelectric conversion regions in the silicon substrate differ depending on a wavelength of incident light. In order to increase the quantum efficiency to the maximum, it is effective to form photoelectric conversion regions in the silicon substrate at a deep position from its surface. The following describes a method disclosed in Patent Literature 1, with reference to FIGS. 5 and 6.

FIG. 5 is a top view of a pixel part of a conventional solid-state imaging device. FIG. 6 is a cross-sectional view of the pixel part of the conventional solid-state imaging device shown in FIG. 5 along a line X-X′. As shown in FIG. 5, a solid-state imaging device, which is especially for use in a digital still camera, has a structure in which R, B, and G (Gr and Gb) three color filters are arranged in the Bayer pattern above photoelectric conversion parts for generating electrical charge.

According to the conventional solid-state imaging device shown in FIG. 6, photodiodes 601, which function as the photoelectric conversion parts for generating electrical charges depending on incident light, are arranged in a matrix so as to alternate with isolation regions 602.

On an n-type semiconductor substrate 603, a p-type well 604 is provided such that the impurity concentration reaches the peak at a deep part of the n-type semiconductor substrate 603. Furthermore, on a part of the p-type well 604 corresponding to the photodiode 601, an n-type second impurity diffusion layer 605 is provided. Above the n-type second impurity diffusion layer 605, an n-type first impurity diffusion layer 606 is provided. On a surface of the n-type first impurity diffusion layer 606, a p-type impurity diffusion layer 607 is provided. Also, in the isolation region 602, a p-type first impurity diffusion layer 608 is provided so as to be adjacent to the photodiode 601. Furthermore, between the p-type well 604 and the p-type first impurity diffusion layer 608, a p-type second impurity diffusion layer 609 is provided so as to have the same pattern as the p-type first impurity diffusion layer 608 or a grid pattern when seen from above the substrate.

Furthermore, in an upper part of the isolation region 602, a transfer electrode wiring 610 is provided. Above the transfer electrode wiring 610, a first insulating layer 611 is provided. Above the first insulating layer 611, a light shielding layer 612 is formed which has an opening for leading incident light to the photodiode 601. Above the light shielding layer 612, a second insulating layer 613 is provided, which is mainly composed of an oxide film, a nitride film, an oxynitride film, or the like. Above the second insulating layer 613, a color filter 614 is provided, which is mainly composed of an organic film. When seen from above the substrate, the color filter 614 is arranged in the three-color Bayer pattern as shown in FIG. 5. Above the color filter 614, a middle layer 615 is provided, which is mainly composed of an organic film. Above the middle layer 615, a lens layer 616 for collecting incident light is provided.

The p-type second impurity diffusion layer 609, which is formed under the p-type first impurity diffusion layer 608, and the n-type second impurity diffusion layer 605, which is formed under the n-type first impurity diffusion layer 606, are formed by a known photo etching technique and highly-accelerated ion implantation technique. This enables formation of a plurality of impurity diffusion layers that are each formed at a different depth from a surface of the substrate.

### CITATION LIST

### Patent Literature

Patent Literature 1 Japanese Patent Application Publication No. 2006-229107

### SUMMARY OF THE INVENTION

### Problems to be Solved by the Invention

However, if the photoelectric conversion parts and the isolation regions are reduced in size with the size reduction of pixel part and so on, it is difficult to form small resist patterns when photo etching is performed in highly-accelerated ion implantation. The following describes a problem of the Patent Literature 1 with reference to FIGS. 7A and 7B.

FIG. 7A shows a resist pattern for forming photoelectric conversion parts of the conventional solid-state imaging device, and FIG. 7B shows a resist pattern for forming isolation regions of the conventional solid-state imaging device.

As shown in FIG. 7A, an insulating layer 708 for buffer, which is an oxide film, a nitride film, or the like, is formed on an n-type semiconductor substrate 701. Then, with use of an ion implantation technique, an n-type first impurity diffusion layer 702 corresponding to photodiode is formed, and an n-type second impurity diffusion layer 703 is formed as an under layer of the n-type first impurity diffusion layer 702. The n-type second impurity diffusion layer 703 is formed by performing highly-accelerated ion implantation. Here, no n-type impurity diffusion layer is formed in the isolation regions. Accordingly, in order to heighten the stopping power of ion implantation in the isolation regions, a thick resist needs to be applied to form a line pattern corresponding to each of the isolation regions. Specifically, in order to implant P (phosphorus) ion species into a silicon substrate at a depth of 4.0 μm, the implantation needs to be performed at an acceleration energy of 6.0 MeV. This necessitates a resist layer thickness 711 to be 5.0 μm. As a result, in order to have a line dimension of 0.5 μm, it is necessary to form a resist pattern 704 having an aspect ratio of 10 (5.0 μm/0.5 μm=10).

With further size reduction of pixel part, further dimension reduction is predicted to proceed. This makes it impossible to perform patterning of a thick resist due to the excess over the resolution limit of the photo etching technology. As a result, it is difficult to form a deep photodiode region, and therefore sufficient sensitivity characteristics cannot be achieved.

Also as shown in FIG. 7B, with use of the ion implantation technique, a p-type first impurity diffusion layer 705 corresponding to the isolation region is formed in the n-type semiconductor substrate 701, and a p-type second impurity diffusion layer 706 is formed as an under layer of the p-type first impurity diffusion layer 705. The p-type second impurity diffusion layer 706 is formed by performing highly-accelerated ion implantation. Here, in order to heighten the ion implantation stopping power in the photodiode regions, a thick resist needs to be applied to form a space pattern corresponding to each of the isolation regions. Specifically, in order to implant B (boron) ion species into a silicon substrate at a depth of 4.0 μm, the implantation needs to be performed at an acceleration energy of 3.0 MeV. This necessitates a resist layer thickness 711 to be 5.0 μm. As a result, in order to have a space dimension (space pattern) of 0.5 μm, it is necessary to form a resist pattern 707 having an aspect ratio of 10. As shown in FIG. 7A, if the line pattern 704 having an aspect ratio of 10 can be formed but the space pattern 707 cannot be formed, separation of the photodiode region is difficult. This causes a problem that sufficient sensitivity characteristics cannot be achieved.

In view of the above problem, the present invention aims to provide a stable and high sensitive solid-state imaging device in which a deep photoelectric conversion region can be formed while size of pixel part becomes reduced.

### Means for Solving the Problems

In order to solve the above problem, the present invention provides a solid-state imaging device comprising: a semiconductor substrate that has a well region of a first conductive type; a first photoelectric conversion region that is formed in the well region, and is composed of impurities of a second conductive type, the second conductive type being opposite to the first conductive type; a second photoelectric conversion region that is formed in the well region, and is composed of impurities of the second conductive type; a third photoelectric conversion region that is formed in the well region at a depth greater than a depth at which the first photoelectric conversion region is formed, and is composed of impurities of the second conductive type; a first color filter that is formed above the semiconductor substrate so as to correspond to the first photoelectric conversion region, and is configured to transmit mainly a first wavelength; and a second color filter that is formed above the semiconductor substrate so as to correspond to the second photoelectric conversion region, and is configured to transmit mainly a second wavelength, wherein the first wavelength is longer than the second wavelength, and the third photoelectric conversion region is formed at a depth shallower than a depth at which the second photoelectric conversion region is formed.

### Advantageous Effect of the Invention

According to the present invention, it is possible to form a deep photoelectric conversion region while size of pixel part becomes reduced, thereby providing a stable and high sensitive solid-state imaging device.

### BRIEF DESCRIPTION OF THE DRAWINGS

FIG. 1 is a top view showing a solid-state imaging device relating to an embodiment of the present invention.

FIG. 2 is a cross-sectional view showing the solid-state imaging device relating to the embodiment of the present invention.

FIG. 3 shows depth dependence of quantum efficiency on a silicon substrate.

FIGS. 4A and 4B each show a resist pattern for forming an impurity diffusion layer relating to the embodiment of the present invention.

FIG. 5 is a top view showing a conventional solid-state imaging device.

FIG. 6 is a cross-sectional view showing the conventional solid-state imaging device.

FIGS. 7A and 7B each show a resist pattern for forming an impurity diffusion layer relating to the conventional solid-state imaging device.

### DESCRIPTION OF THE PREFERRED EMBODIMENTS

### Embodiment

The following describes a solid-state imaging device relating to an embodiment of the present invention and a manufacturing method thereof, with reference to FIGS. 1 to 4.

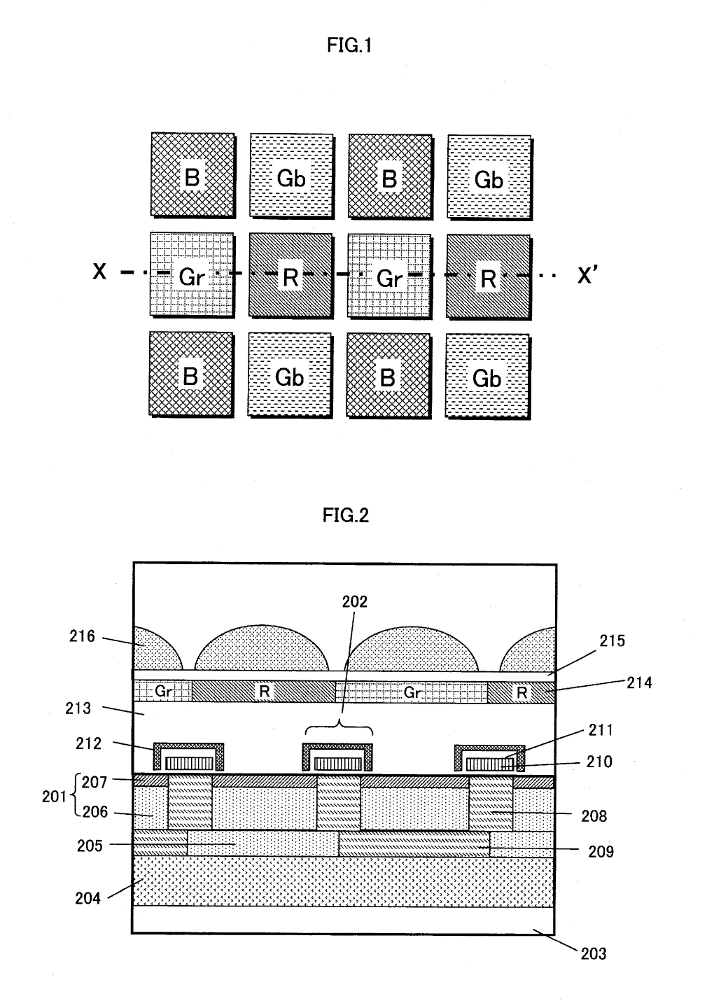

FIG. 1 is a top view of a pixel part of the solid-state imaging device relating to the embodiment of the present invention. FIG. 2 is a cross-sectional view of the pixel part of the solid-state imaging device shown in FIG. 1 along a line X-X′. As shown in FIG. 1, a solid-state imaging device, which is especially for use in a digital still camera, has a structure in which R, B, and G (Gr and Gb) three color filters are arranged in the Bayer pattern above a photoelectric conversion part for generating electrical charges.

According to the solid-state imaging device shown in FIG. 2, photodiodes 201, which functions as the photoelectric conversion parts for generating electrical charges depending on incident light, are arranged in a matrix so as to alternate with isolation regions 202.

On an n-type semiconductor substrate 203, a p-type well 204 is provided such that the impurity concentration reaches the peak at a deep part of the n-type semiconductor substrate 203. Furthermore, on a part of the p-type well 204 corresponding to the photodiode 201, an n-type first impurity diffusion layer 206 is provided. On a surface of the n-type first impurity diffusion layer 206, a p-type impurity diffusion layer 207 is provided. Also, in the isolation region 202, a p-type first impurity diffusion layer 208 is provided so as to be adjacent to the photodiode 201.

Furthermore, at a position deeper than the n-type first impurity diffusion layer 206 in the p-type well 204 on the n-type semiconductor substrate 203, an n-type second impurity diffusion layer 205 is provided only in a photodiode region corresponding to the red (R) color filter, and a p-type second impurity diffusion layer 209 for isolating pixels is provided in a photodiode region corresponding to the blue (B) and green (Gr, Gb) color filters.

Furthermore, in an upper part of the isolation region 202, a transfer electrode wiring 210 is provided. Above the transfer electrode wiring 210, a first insulating layer 211 is provided. Above the first insulating layer 211, a light shielding layer 212 is formed which has an opening for leading incident light to the photodiode 201. Above the light shielding layer 212, a second insulating layer 213 is provided, which is mainly composed of an oxide film, a nitride film, an oxynitride film, or the like. Above the second insulating layer 213, a color filter 214 is provided, which is mainly composed of an organic film. When seen from above the substrate, the color filter 214 is arranged in the three-color Bayer pattern as shown in FIG. 1. Above the color filter 214, a middle layer 215 is provided, which is mainly composed of an organic film. Above the middle layer 215, a lens layer 216 for collecting incident light is provided.

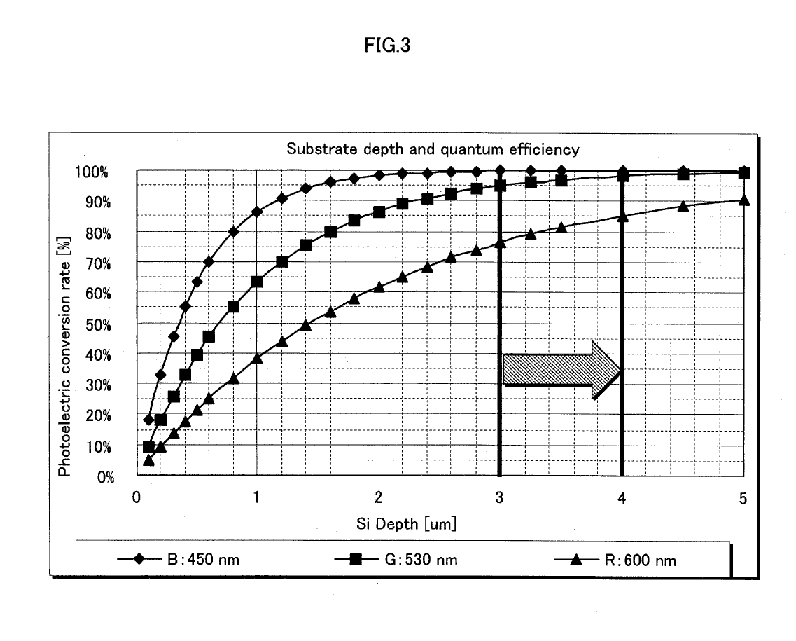

FIG. 3 shows depth dependence of quantum efficiency on a silicon substrate. A region where photoelectric conversion is performed on incident light in the silicon substrate differs depending on a wavelength of the incident light. As shown in FIG. 3, at a depth of 3 μm from the surface of the silicon substrate, while photoelectric conversion is performed on 100% of blue incident light and approximately 95% of green incident light, photoelectric conversion is performed on only 75% of red incident light. By forming a photodiode region in the silicon substrate so as to reach a depth of 4 μm from the surface of the silicon substrate, quantum efficiency for red light improves up to 85%, and as a result, the sensitivity to red light improves by approximately 13%. Compared with this, the sensitivity to blue and green light can hardly be expected to improve. As described above, red light has the longest wavelength, and the sensitivity characteristics are difficult to be maintained. In view of further size reduction of pixel part, it is the most important to improve the sensitivity to red light. Accordingly, by forming only a photodiode region corresponding to red pixels in the silicon substrate so as to reach a deep position from the surface of the silicon substrate, it is possible to sufficiently improve the sensitivity.

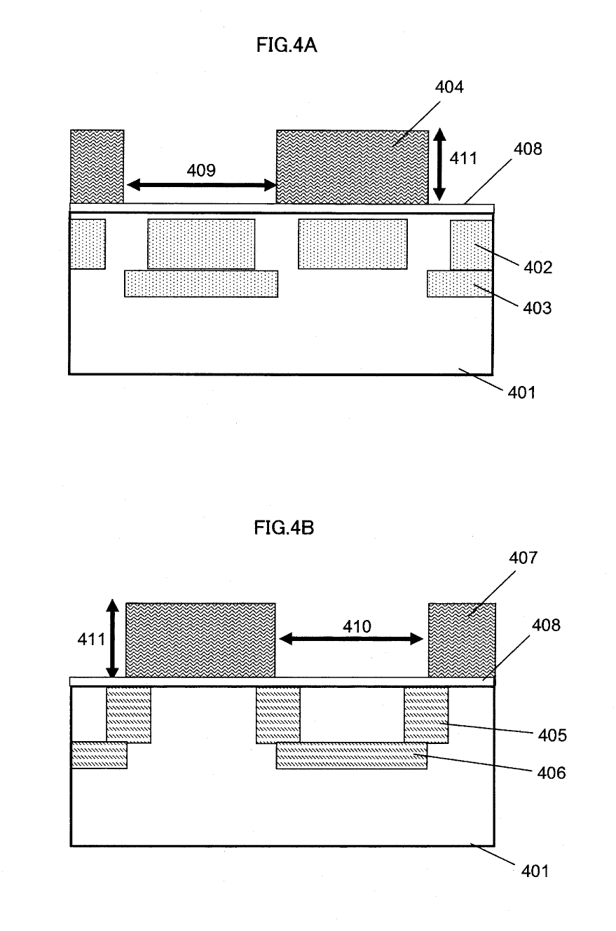

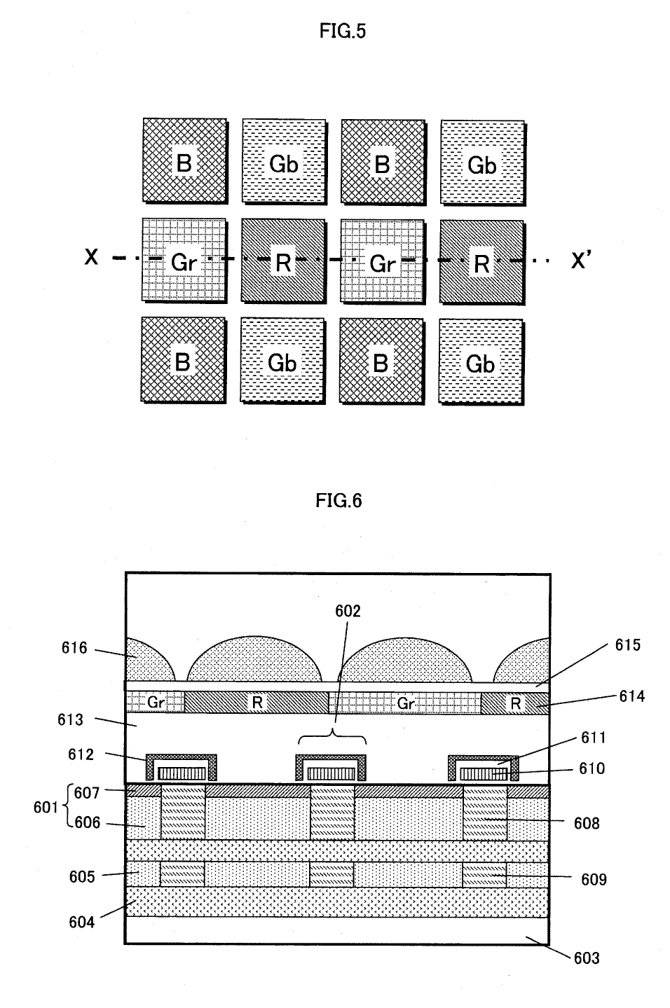

FIG. 4A shows a resist pattern for forming a photoelectric conversion part, especially a red photodiode, in the solid-state imaging device relating to the embodiment of the present invention. FIG. 4B shows a resist pattern for forming an isolation region in the solid-state imaging device relating to the embodiment of the present invention.

According to FIG. 4A, a blue photodiode and a green photodiode have been already formed. In other words, at a time when an upper half part of the red photodiode is formed, the blue photodiode and the green photodiode are formed (not shown). Accordingly, formation of the upper half part of the red photodiodes means completion of the green and blue photodiodes.

As shown in FIG. 4A, in the n-type semiconductor substrate 401, an n-type first impurity diffusion layer 402 is formed, which corresponds to green and blue photodiodes and the upper half part of a red photodiode. Highly-accelerated ion implantation is performed such that an n-type second impurity diffusion layer 403 is formed only in a photodiode region corresponding to the red pixels. In order to implant P (phosphorus) ion species into a silicon substrate at a depth of 4.0 μm, the implantation needs to be performed at an acceleration energy of 6.0 MeV. This necessitates a resist layer thickness 411 to be 5.0 μm.

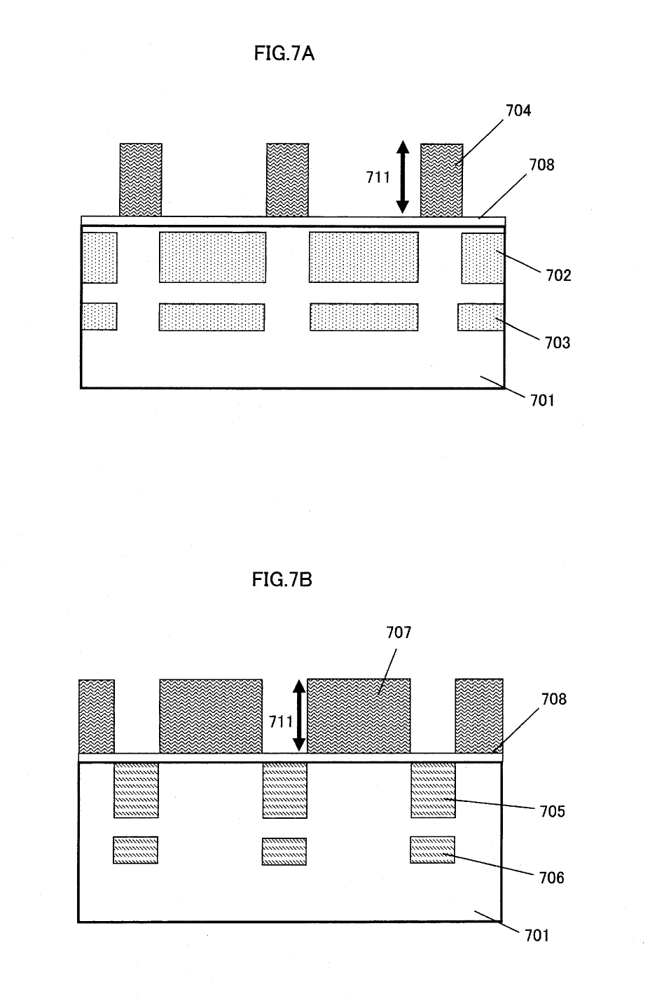

In order to perform pattern formation to form an impurity diffusion layer in all of the photodiode regions corresponding to the red, blue, and green pixels, it is necessary to form a line dimension of 0.5 μm for the resist pattern 704 corresponding to the isolation regions (see FIG. 7A). However, according to the present invention, pattern formation is performed to form an impurity diffusion layer only in the photodiode regions corresponding to the red pixels. Accordingly, it is unnecessary to perform etching on the resist films on the photodiode regions corresponding to the blue and green pixels, and this eliminates the need to considerate isolation of the red pixels from adjacent other color pixels. As a result, if the cell size (according to the one-pixel one-cell structure, one pixel size is equal to one cell size) is 1.5 μm, a line dimension 409 is increased up to the cell size, namely, approximately 1.5 μm. This decreases the aspect ratio of the resist pattern 404 to approximately 3.3, compared with the conventional aspect ratio of 10. As a result, the accuracy of the photo etching process improves by the decrease.

Also, as shown in FIG. 4B, the p-type first impurity diffusion layer 405 corresponding to the isolation region is formed in the n-type semiconductor substrate 401. Highly-accelerated ion implantation is performed such that the p-type second impurity diffusion layer 406 is formed under the photodiode regions corresponding to the blue and green pixels at a position deeper than the p-type first impurity diffusion layer 405. In order to implant P (phosphorus) ion species into a silicon substrate at a depth of 4.0 μm, the implantation needs to be performed at an acceleration energy of 3.0 MeV. This necessitates a resist layer thickness 411 to be 5.0 μm.

Here, as shown in FIG. 7B, in order to perform pattern formation to form an impurity diffusion layer in each of the red, blue, and green isolation regions, it is necessary to form a space dimension of 0.5 μm corresponding to the isolation regions. However, according to the present embodiment, the n-type impurity diffusion layer 403, which is formed in the semiconductor substrate at a deep position from the surface, is formed only in the photodiode region corresponding to the red pixels. In other words, the p-type second impurity diffusion layer 406, which is formed in the semiconductor substrate at a deep position from the surface, is formed only in the photodiode regions corresponding to the blue and green pixels. Accordingly, it is only necessary to remain a resist film only in the photodiode regions corresponding to the red pixels, and this eliminates the need to considerate isolation of the red pixels from adjacent other color pixels. As a result, if the cell size is 1.5 μm, a space dimension 410 is increased up to the cell size, namely, approximately 1.5 μm. This decreases the aspect ratio of the resist pattern 407 from 10 to approximately 3.3, and as a result photo etching process can be easily performed. With further size reduction of pixel part, further dimension reduction is predicted to proceed. However, according to the present embodiment, it is possible to stably form deep photodiode regions and isolation regions while size of pixel part becomes reduced. This can achieve sufficient sensitivity characteristics.

Also, the n-type second impurity diffusion layer 403 may be in contact with the p-type second impurity diffusion layer 406, and the aspect ratio of them is small. Accordingly, it may be possible to increase the size of the n-type second impurity diffusion layer 403 a little larger than the cell size, and decrease the size of the p-type second impurity diffusion layer 406 a little smaller than the cell size. Specifically, the n-type second impurity diffusion layer 403 may have 1.6 μm and the p-type second impurity diffusion layer 406 may have 1.4 μm, and vice versa. If the size of the n-type second impurity diffusion layer 403 is increased, it is possible to further improve the sensitivity to red light. If the size of the p-type second impurity diffusion layer 406 is increased, it is possible to reduce color mixing due to incident lights into adjacent pixels.

Also, the size reduction of pixel part sometimes causes such a color mixing. However, according to the embodiment, it is possible to stably form a deep photodiode region, thereby achieving a carrier capture effect at the deep region. This results in suppression of the color mixing.

According to the embodiment of the present invention, a deep photodiode region is formed so as to correspond to only red pixels. This halves the required accuracy of forming a resist pattern in highly-accelerated ion implantation, thereby easily performing process. As a result, it is possible to form a deep photodiode region while the size of pixel part becomes reduced. This can realize a solid-state imaging device having preferable sensitivity characteristics.

The following describes the manufacturing method of the solid-state imaging device relating to the embodiment of the present invention, in the order of processes.

Process 1: A p-type well 204 is formed in an n-type semiconductor substrate 203 by an ion implantation technique employing highly-accelerated energy.

Process 2: In a region in which a photodiode 201 is to be formed, an n-type first impurity diffusion layer 206 is formed in a region corresponding to the p-type well 204 by a known photo etching technique and the ion implantation technique employing highly-accelerated energy.

Process 3: In a photodiode region corresponding to red pixels, the n-type second impurity diffusion layer 205 is formed by the known photo etching technique and the ion implantation technique employing highly-accelerated energy. Specifically, as shown in FIG. 4A, a buffer-use insulating layer 408, which is made of an oxide film, a nitride film, or the like, is formed above the n-type semiconductor substrate 401. Then, photoresist films are deposited on a top surface of the buffer-use insulating layer 408.

Process 4: Patterning is performed on the deposited photoresist films by a photoresist process or the like so as to be etched. As a result, a predetermined resist pattern 404 having an implantation opening 409 is formed at a position where an n-type second impurity diffusion layer 403 is to be formed.

Process 5: N-type impurity ions such as arsenic and phosphorus are implanted into the n-type semiconductor substrate 401 at a predetermined depth at a highly-accelerated voltage. Also, n-type impurity ions such as arsenic and phosphorus are implanted into the n-type semiconductor substrate 401 at a position that is shallower than the predetermined depth at a different highly-accelerated voltage.

Process 6: The resist pattern 404 is removed, and then thermal process is performed to recover crystal defects due to the ion plantation.

Process 7: In a region where the isolation region 202 is to be formed, an n-type first impurity diffusion layer 208 is formed by the known photo etching technique and ion implantation technique employing highly-accelerated energy.

Process 8: In photodiode regions corresponding to blue and green pixels, a p-type second impurity diffusion layer 209 is formed by the known photo etching technique and ion implantation technique employing highly-accelerated energy. Specifically, as shown in FIG. 4B, the buffer-use insulating layer 408, which is made of an oxide film, a nitride film, or the like, is formed above the n-type semiconductor substrate 401. Then, photoresist films are deposited on a top surface of the buffer-use insulating layer 408.

Process 9: Patterning is performed on the deposited photoresist films by the photoresist process or the like so as to be etched. As a result, a predetermined resist pattern 407 having an implantation opening 410 is formed at a position where a p-type second impurity diffusion layer 406 is to be formed.

Process 10: P-type impurity ions such as boron are implanted into the n-type semiconductor substrate 401 at a predetermined depth at a highly-accelerated voltage. Also, p-type impurity ions such as boron are implanted into the n-type semiconductor substrate 401 at a position that is shallower than the predetermined depth at a different highly-accelerated voltage.

Process 11: The resist pattern 407 is removed, and then thermal process is performed to recover crystal defects due to the ion plantation.

Process 12: A known manufacturing process is performed to form a solid-state imaging device shown in FIGS. 1 and 2.

Note that it may be possible to reverse the above-described order of ion implantation for forming the n-type first impurity diffusion layer 402 and the n-type second impurity diffusion layer 403. Also, it may be possible to reverse the above-described order of ion implantation for forming the p-type first impurity diffusion layer 405 and the p-type second impurity diffusion layer 406.

Also, in the above embodiment, an n-type impurity diffusion layer has been described using the examples of an n-type first impurity diffusion layer and an n-type second impurity diffusion layer. Alternatively, the n-type impurity diffusion layer having a multilayer structure may be employed in which an n-type third impurity diffusion layer and an n-type fourth impurity diffusion layer are provided between the n-type first impurity diffusion layer and the n-type second impurity diffusion layer.

In the above embodiment, a p-type impurity diffusion layer has been described using the examples of the p-type first impurity diffusion layer and the p-type second impurity diffusion layer. Alternatively, the p-type impurity diffusion layer having a multilayer structure may be employed in which a p-type third impurity diffusion layer and a p-type fourth impurity diffusion layer are provided between the p-type first impurity diffusion layer and the p-type second impurity diffusion layer.

Furthermore, in the above embodiment, the effects has been described using the example of a CCD sensor. Alternatively, the same effects can be achieved using a MOS sensor.

Through the manufacture including the highly-accelerated ion implantation process as described above, the n-type second impurity diffusion layer 403 can be formed at an appropriate position corresponding to red pixels in the photodiode region of the n-type semiconductor substrate 401. This can achieve a solid-state imaging device having desired characteristics.

### INDUSTRIAL APPLICABILITY

As have been described above, the solid-state imaging device relating to the present invention has preferable sensitivity characteristics while pixel size becomes reduced and high integration proceeds. Specifically, the solid-state imaging device relating to the present invention is preferably useful for use in camera-equipped mobile phones, video cameras, digital still cameras, and the like.

### REFERENCE SIGNS LIST

201 and 601: photodiode
202 and 602: isolation region
203 and 603: n-type semiconductor substrate
204 and 604: p-type well
205 and 605: n-type second impurity diffusion layer
206 and 606: n-type first impurity diffusion layer
207 and 607: p-type impurity diffusion layer
206 and 608: p-type first impurity diffusion layer
209 and 609: p-type second impurity diffusion layer
210 and 610: transfer electrode wiring
211 and 611: first insulating layer
212 and 612: light shielding layer
213 and 613: second insulating layer
214 and 614: color filter
215 and 615: middle layer
216 and 616: lens layer
401 and 701: n-type semiconductor substrate
402 and 702: n-type first impurity diffusion layer
403 and 703: n-type second impurity diffusion layer
404 and 704: line resist pattern
405 and 705: p-type first impurity diffusion layer
406 and 706: p-type second impurity diffusion layer
407 and 707: space resist pattern
408 and 708: buffer-use insulating film
409: opening that corresponds to n-type second impurity diffusion layer
410: opening that corresponds to p-type second impurity diffusion layer
411 and 711: resist layer thickness

What is claimed is:

1. A solid-state imaging device comprising:
a semiconductor substrate that has a well region of a first conductive type;
a first photoelectric conversion region that is formed in the well region, and is composed of impurities of a second conductive type, the second conductive type being opposite to the first conductive type;
a second photoelectric conversion region that is formed in the well region, and is composed of impurities of the second conductive type;
a third photoelectric conversion region that is formed in the well region at a depth greater than a depth at which the first photoelectric conversion region is formed, and is composed of impurities of the second conductive type;
a first color filter that is formed above the semiconductor substrate so as to correspond to the first photoelectric conversion region, and is configured to transmit mainly a first wavelength; and
a second color filter that is formed above the semiconductor substrate so as to correspond to the second photoelectric conversion region, and is configured to transmit mainly a second wavelength, wherein
the first wavelength is longer than the second wavelength, and
the third photoelectric conversion region is formed at a depth shallower than a depth at which the second photoelectric conversion region is formed.

2. The solid-state imaging device of claim 1, wherein
a surface of the third photoelectric conversion region that is parallel to a main surface of the semiconductor substrate is larger in area than a surface of the first photoelectric conversion region that is parallel to the main surface of the semiconductor substrate.

3. The solid-state imaging device of claim 1, further comprising
a separation region that is formed in the well region at a depth greater than the depth at which the second photoelectric conversion region is formed, and is composed of impurities of the first conductive type.

4. The solid-state imaging device of claim 1, wherein
the third photoelectric conversion region is adjacent to a separation region composed of impurities of the first conductive type.

5. The solid-state imaging device of claim 1, wherein
the first photoelectric conversion region has a depth of 4 μm or less.

6. The solid-state imaging device of claim 1, wherein
the third photoelectric conversion region has a depth of 4 μm or more.

7. A manufacturing method of a solid-state imaging device comprising:
a first process of forming a well region of a first conductive type in a semiconductor substrate;
a second process of forming a first photoelectric conversion region and a second photoelectric conversion region by implanting impurities of a second conductive type into the well region, the second conductive type being opposite to the first conductive type;
a third process of forming a third photoelectric conversion region at a depth shallower than a depth at which the second photoelectric conversion region is formed, by implanting impurities of the second conductive type into the well region;
a fourth process of forming, above the semiconductor substrate so as to correspond to the first photoelectric conversion region, a first color filter configured to transmit mainly a first wavelength; and
a fifth process of forming, above the semiconductor substrate so as to correspond to the second photoelectric conversion region, a first color filter configured to transmit mainly a second wavelength that is shorter than the first wavelength.
